(19) United States
(12) Patent Application Publication
(10) Pub. No.: US 2012/0204932 A1
(43) Pub. Date: Aug. 16, 2012

(54) THIN-FILM SOLAR BATTERY MODULE AND METHOD FOR MANUFACTURING THE SAME

(75) Inventors: Kazuyo Endo, Tokyo (JP); Jun Fujita, Tokyo (JP); Takashi Tokunaga, Tokyo (JP)

(73) Assignee: MITSUBISHI ELECTRIC CORPORATION, TOKYO (JP)

(21) Appl. No.: 13/503,474

(22) PCT Filed: Oct. 20, 2010
(86) PCT No.: PCT/JP10/68516

§ 371 Date: Apr. 23, 2012

(30) Foreign Application Priority Data
Nov. 5, 2009 (JP) 2009-253874

(51) Int. Cl. H01L 31/05; H05K 3/02; H01L 31/18

(52) U.S. Cl. 136/244; 29/890.033; 29/846

(57) ABSTRACT

A thin-film solar battery module that can avoid a decrease in power generation efficiency caused by influences of meandering of a wiring material, relax a stress due to a difference in a thermal expansion coefficient between a substrate material and the wiring material, and suppress warpage of a substrate and separation of a joined part of an electrode and a wiring. The thin-film solar battery module includes a thin-film solar battery device including serially connecting a plurality of thin-film solar battery cells to each other and a bus bar wiring provided at a positive-side end and a negative-side end of the thin-film solar battery device. Additionally, the bus bar wiring couples a plurality of conductive members to each other in a partially superimposed manner.

### FIELD

The present invention relates to a thin-film solar battery module and a method for manufacturing the same.

### BACKGROUND

A thin-film solar battery module that uses amorphous silicon as a power generation layer is constituted by connecting a plurality of thin-film solar battery cells to each other. In a thin-film solar battery cell, a transparent electrode film, a photoelectric conversion layer, and a back surface electrode are successively stacked on a translucent substrate. The thin-film solar battery cell is formed in a strip shape. One transparent electrode film is connected to the other back surface electrode between adjacent thin-film solar battery cells, so that a thin-film solar battery device with a plurality of thin-film solar battery cells being serially connected to each other therein is formed. In such a thin-film solar battery device, a current collecting wiring called “bus bar wiring” is formed at an end of a thin-film solar battery cell at one end of the device and at an end of a thin-film solar battery cell at the other end of the device, respectively. For example, Patent Literature 1 proposes a technique of a thin-film solar battery module that has a positive current-collecting part and a negative current-collecting part serving as the bus bar wiring. The positive current-collecting part is joined to the entire surface of a P-type electrode terminal and the negative current-collecting part is joined to the entire surface of an N-type electrode terminal by soldering or a conductive paste. The P-type electrode terminal and the N-type electrode terminal are an electrode drawing part that is formed in a linear shape with substantially the same length as a thin-film solar battery cell.

As the thin-film solar battery module, there is a module that uses an interconnector for connecting a plurality of thin-film solar battery cells having a semiconductor substrate and a current collecting electrode on a front surface and a back surface of the substrate to each other is provided. One front-surface-side current collecting electrode is connected to the other back-surface-side current collecting electrode by the interconnector between adjacent thin-film solar battery cells. The interconnector is joined to the current collecting electrode by soldering, for example. For instance, Patent Literature 2 proposes a technique of a thin-film solar battery module that has an interconnector with which an uneven part is provided in advance. At the time of heating and cooling in a manufacturing process of the thin-film solar battery module, expansion and contraction are made to occur along an unevenness direction of the interconnector, so that a compressive stress applied to a semiconductor substrate is reduced. By a reduction in the compressive stress, generation of warpage of the semiconductor substrate and separation of a joined part of the interconnector and the current collecting electrode are suppressed.

### CITATION LIST

### Patent Literatures

Patent Literature 1: Japanese Patent Application Laid-open No. 2000-68542
Patent Literature 2: Japanese Patent Application Laid-open No. 2005-302902
Patent Literature 3: Japanese Patent Application Laid-open No. 2009-81317

### SUMMARY

### Technical Problem

However, meandering and twist are generated in a wiring material used for the interconnector connecting between crystal solar battery elements and the bus bar wiring for a thin-film solar battery during manufacturing of the wiring material. Therefore, when the wiring material with meandering and twist occurring therein is used as a wiring, in a case of a crystal solar battery, as shown in Patent Literature 3, for example, the interconnector blocks a light receiving surface of the solar battery element. In a case of the thin-film solar battery, the bus bar wiring protrudes from an area where a wiring is formed to enter cells of the solar battery, so that a short-circuit occurs. In both cases, a decrease in power generation efficiency of solar batteries may occur. According to the case of Patent Literature 3, a device of forming interconnectors is provided with a mechanism of pulling a wiring material, so that bending of the wiring material is partially corrected. However, such a device for performing correction may become considerably expensive.

By thermal expansion during heating and contraction during cooling in the manufacturing process of the thin-film solar battery module, a stress due to a difference in a thermal expansion coefficient between the substrate and the bus bar wiring of the thin-film solar battery module is generated. When the bus bar wiring having substantially the same length as the thin-film solar battery cell is directly joined to the thin-film solar battery cell or joined via an electrode terminal thereto as in the technique of Patent Literature 1, a stress is applied to the entire bus bar wiring and thus it is difficult to suppress warpage of the substrate and separation of a connected part of the electrode and the wiring. In the case of the technique of Patent Literature 2, because unevenness has to be formed in advance in the wiring material serving as the interconnector, a wiring-connection forming step is complicated. Further, because the stress easily concentrates on a bent part of the interconnector, a structure may be weakened. The unevenness of the interconnector may be flattened in laminate processing performed by covering the interconnector with a filling material and a back sheet after the interconnector is mounted. Furthermore, because a space is formed between a convex part of the unevenness of the interconnector and the current collecting electrode, when water enters the module, the water easily concentrates on the space.

The present invention has been achieved in view of the above problems, and an object of the invention is to provide a thin-film solar battery module that can avoid a decrease in power generation efficiency caused by influences of meandering of a wiring material, to relax a stress due to a difference in a thermal expansion coefficient between a substrate material and a wiring material, and to suppress warpage of a substrate and separation of a joined part of an electrode and a wiring, and to provide a method for manufacturing the thin-film solar battery module.

### Solution to Problem

In order to solve the above problem and in order to attain the above object, a thin-film solar battery module of the present invention, includes: a thin-film solar battery device constituted by serially connecting a plurality of thin-film solar battery cells to each other; and a bus bar wiring provided at a positive-side end and a negative-side end of the thin-film solar battery device. Additionally, the bus bar wiring is constituted by coupling a plurality of conductive members to each other in a partially superimposed manner.

### Advantageous Effects of Invention

According to the present invention, a decrease in power generation efficiency caused by influences of meandering of a wiring material can be avoided, a stress due to a difference in a thermal expansion coefficient between a substrate material and the wiring material can be relaxed, and warpage of a substrate and separation of a connected part of an electrode and a wiring can be suppressed.

### BRIEF DESCRIPTION OF DRAWINGS

FIG. 1 depicts a plane schematic configuration of a back side of a thin-film solar battery module according to a first embodiment.

FIG. 2 depicts a schematic configuration of an A-A cross-section of the thin-film solar battery module shown in FIG. 1.

FIG. 3-1 depicts a schematic cross-sectional configuration in respective processes of a bus-bar-wiring forming step in a method for manufacturing the thin-film solar battery module.

FIG. 3-2 depicts a schematic cross-sectional configuration in respective processes of the bus-bar-wiring forming step in the method for manufacturing the thin-film solar battery module.

FIG. 4-1 depicts a plane schematic configuration of a back surface side in respective processes of the bus-bar-wiring forming step.

FIG. 4-2 depicts a plane schematic configuration of the back surface side in respective processes of the bus-bar-wiring forming step.

FIG. 5 depicts a schematic cross-sectional configuration in respective processes of a bus-bar-wiring forming step in a method for manufacturing a thin-film solar battery module according to a second embodiment.

FIG. 6 is an explanatory diagram of a modification of the second embodiment.

FIG. 7 depicts a schematic cross-sectional configuration in respective processes of a bus-bar-wiring forming step in a method for manufacturing a thin-film solar battery module according to a third embodiment.

FIG. 8 is an explanatory diagram of a modification of the third embodiment.

FIG. 9 is an explanatory diagram of another modification of the third embodiment.

### DESCRIPTION OF EMBODIMENTS

Exemplary embodiments of a thin-film solar battery module and a method for manufacturing the same according to the present invention will be explained below in detail with reference to the accompanying drawings.

### First Embodiment

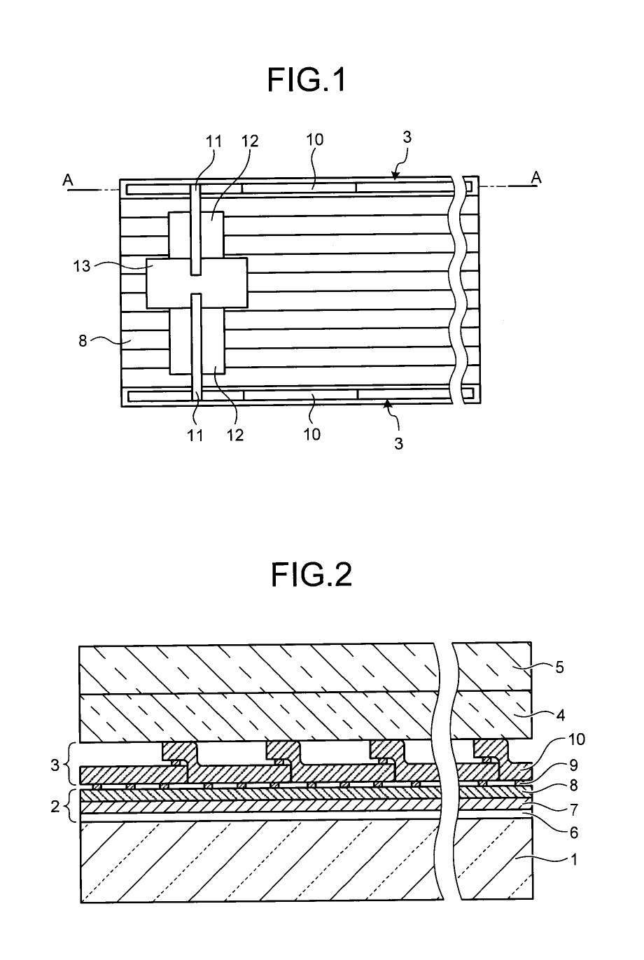

FIG. 1 depicts a plane schematic configuration of a back side of a thin-film solar battery module according to a first embodiment of the present invention. FIG. 2 depicts a schematic configuration of an A-A cross-section of the thin-film solar battery module shown in FIG. 1. In the thin-film solar battery module, a surface that sunlight enters is determined as a front surface and a surface opposite to the front surface is determined as a back surface.

The thin-film solar battery module includes a transparent conductive film 6, a photoelectric conversion layer 7, and a back surface electrode 8 sequentially stacked on a translucent substrate 1 such as glass. The transparent conductive film 6 is constituted by a conductive transparent oxide-film, such as SnO₂, ZnO₂, or ITO. The photoelectric conversion layer 7 is constituted by an amorphous silicon film, for example. The back surface electrode 8 is constituted by using metal such as Ag, Al, or Ti or a metal compound and formed to a film thickness, for example, equal to or less than 1 micrometer.

A thin-film solar battery cell is an elongated strip shape and its longitudinal-direction size substantially coincides with a full width of the translucent substrate 1. The AA cross-section is determined as a cross-section parallel to the longitudinal direction of the thin-film solar battery cell. A thin-film solar battery device 2 is constituted by a plurality of thin-film solar battery cells juxtaposed in a direction vertical to the longitudinal direction. One transparent conductive film 6 is connected to the other back surface electrode 8 between adjacent thin-film solar battery cells, so that the thin-film solar battery device 2 with a plurality of solar battery cells being serially connected to each other therein is formed.

A bus bar wiring 3 is provided on the thin-film solar battery device 2. The bus bar wiring 3 is a drawing electrode for drawing power output from the thin-film solar battery device 2, and provided at a positive-side end and a negative-side end of the thin-film solar battery device 2, respectively. The bus bar wiring 3 is formed in a linear shape along the longitudinal direction of the thin-film solar battery cell.

The bus bar wiring 3 is constituted by coupling a plurality of conductive members 10 to each other. A conductive member 10 is formed to be shorter than the longitudinal direction size of the thin-film solar battery cell. A coupled part of the conductive members 10 is constituted by joining a part of one conductive member 10 on a part of the other conductive member 10 via a joining member 9. Among the conductive member 10, a part except for the part joined to the other conductive member 10 is joined via the joining member 9 to the back surface electrode 8. Both the joining member 9 for joining the conductive members 10 to each other and the joining member 9 for joining the conductive member 10 and the back surface electrode 8 are interspersed in positions except for an end of the conductive member 10.

A concentrated wiring 11 is provided to be vertical to two bus bar wirings 3. The concentrated wiring 11 is electrically connected to the bus bar wiring 3. An insulating film 12 is interposed between the back surface electrode 8 and the concentrated wiring 11. The insulating film 12 is provided for preventing a short-circuit between the thin-film solar battery cell and the concentrated wiring 11.

A filling material 4 and a back sheet 5 are provided by sequentially stacked on the thin-film solar battery device 2 with the bus bar wiring 3 and the concentrated wiring 11 being formed thereon. The filling material 4 and the back sheet 5 protect the back surface side of the thin-film solar battery module. FIG. 1 depicts the configuration when a part covered by the filling material 4 and the back sheet 5 is viewed in a perspective manner. A part to which the concentrated wiring 11 is connected is omitted in FIG. 2.

A terminal end of the concentrated wiring 11 penetrates the filling material 4 and the back sheet 5 and is connected to an externally-connectable cable within a terminal box 13. A mounting interface within the terminal box 13 is subjected to a sealing process for insulation, if necessary. While wires are wired to the bipolar terminal box 13 via the concentrated wirings 11 formed by two bus bar wirings 3 serving as a positive electrode and a negative electrode, respectively, the terminal box 13 can be provided for each of the positive and negative electrodes.

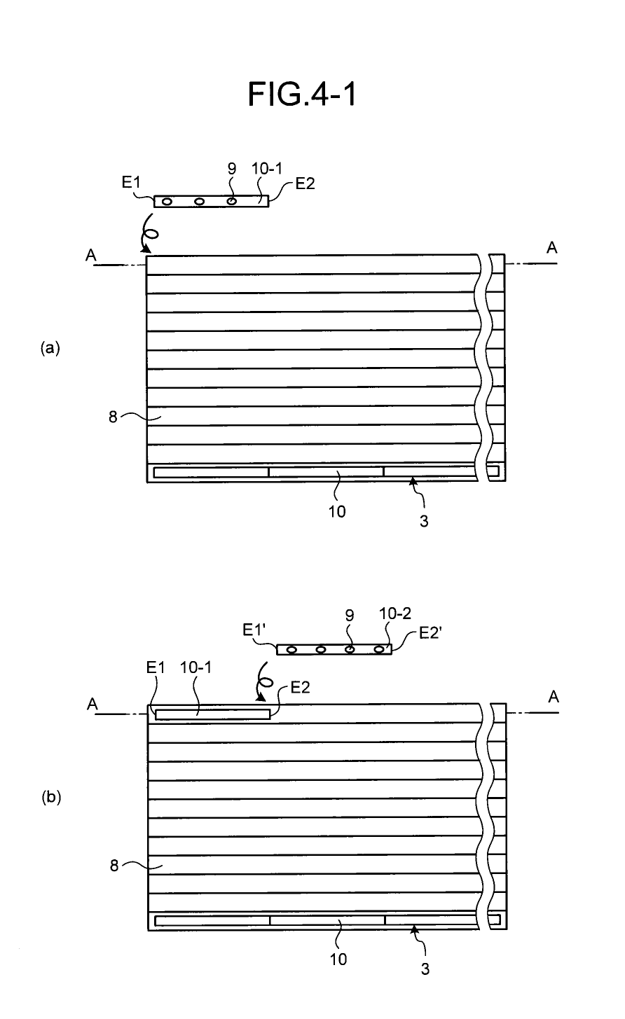

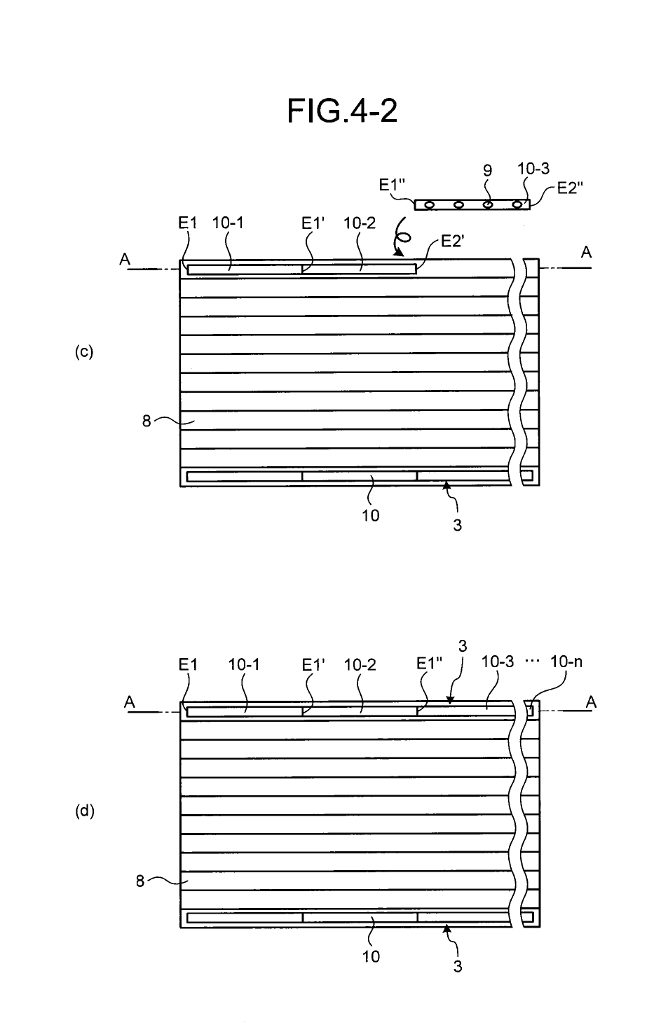

FIGS. 3-1 and 3-2 depict schematic cross-sectional configurations in the respective processes of a bus-bar-wiring forming step in a method for manufacturing the thin-film solar battery module according to the present embodiment. FIGS. 4-1 and 4-2 depict plane schematic configurations of the back surface side in the respective processes of the bus-bar-wiring forming step. Cross-sections shown in FIGS. 3-1 and 3-2 are determined as AA cross-sections shown in FIGS. 4-1 and 4-2.

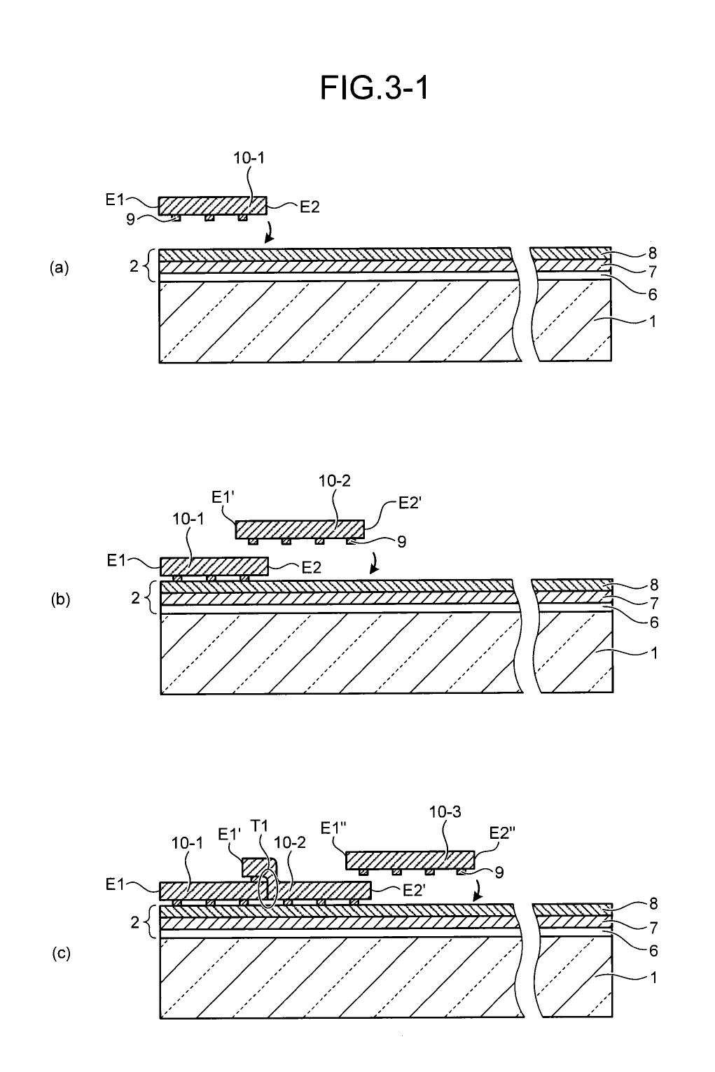

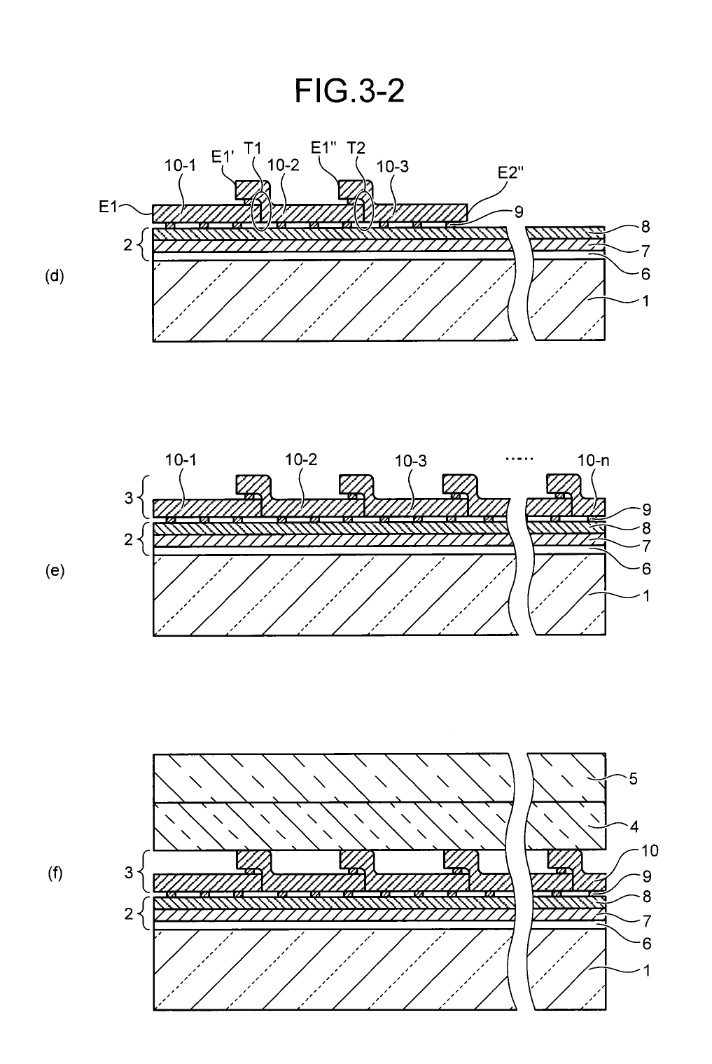

Prior to a process shown in FIG. 3-1(a), the thin-film solar battery device 2 with a plurality of thin-film solar battery cells being serially connected to each other therein is formed on the translucent substrate 1. The thin-film solar battery device 2 is formed by sequentially film-forming the transparent conductive film 6, the photoelectric conversion layer 7, and the back surface electrode 8. The back surface electrode 8 is formed by, for example, vacuum deposition and reactive sputtering.

In the process shown in FIGS. 3-1(a) and 4-1(a), a first conductive member 10-1 is mounted on the back surface electrode 8 of the thin-film solar battery device 2 stacked on the translucent substrate 1. A surface of the conductive member 10-1 opposing the back surface electrode 8 is interspersed with the joining members 9 in advance.

The joining members 9 are interspersed in positions other than ends E1 and E2 of the conductive member 10-1. The conductive member 10-1 is joined via the joining member 9 to the back surface electrode 8. By hardening the joining member 9 by thermal treatment or the like depending on the used material, electrical connection between the conductive member 10-1 and the back surface electrode 8 is formed.

In the process shown in FIGS. 3-1(b) and 4-1(b), a second conductive member 10-2 is mounted. A part of the second conductive member 10-2 on the side of a first end E1′ is joined via the joining member 9 to a part of the first conductive member 10-1 on the side of the second end E2 in a superimposed manner. The second conductive member 10-2 is bent from the part superimposed on the first conductive member 10-1 toward the side of the back surface electrode 8. A part of the second conductive member 10-2 on the side of a second end E2′ with respect to the bent part is joined via the joining member 9 to the back surface electrode 8. In this way, as shown in FIG. 3-1(c), the conductive members 10-1 and 10-2 that have a coupled part with a part of one conductive member 10-2 being joined on a part of the other conductive member 10-1 therein are formed on the back surface electrode 8.

In the process shown in FIGS. 3-1(c) and 4-2(c), a third conductive member 10-3 is mounted like the second conductive member 10-2. A part of the third conductive member 10-3 on the side of a first end E1″ is joined via the joining member 9 to a part of the second conductive member 10-2 on the side of the second end E2′ in a superimposed manner. A part of the third conductive member 10-3 on the side of a second end E2″ with respect to a bent part is joined via the joining member 9 to the back surface electrode 8. As shown in FIG. 3-2(d), a coupled part of the conductive members 10-2 and 10-3 is constituted by joining a part of one conductive member 10-3 on the side of the first end E1″ on a part of the other conductive member 10-2 on the side of the second end E2′.

In this way, the next conductive member 10 is joined to the conductive member 10 previously joined to the back surface electrode 8 and to the back surface electrode 8 so as to be extended over them, and this is sequentially repeated. Consequently, as shown in FIGS. 3-2(e) and 4-2(d), the bus bar wiring 3 with plural conductive members 10-1 to 10-n being coupled to each other therein is formed on the back surface electrode 8.

Next, as shown in FIG. 3-2(f), the filling material 4 and the back sheet 5 are sequentially laid on the thin-film solar battery device 2 with the bus bar wiring 3 being formed thereon. An opening penetrating the concentrated wiring 11 (see FIG. 1) is formed in advance in the filling material 4 and the back sheet 5, and vacuum laminate processing is performed with a connected part of the concentrated wiring 11 on the side of the terminal box 13 while being externally taken out. The terminal box 13 is then adhered on the back sheet 5 and an end of the concentrated wiring 11 is soldered to a terminal within the terminal box 13. For waterproofing, the terminal box 13 is adhered to the back sheet 5 by a resin such as silicon, and the same resin material is filled in the terminal box 13. The thin-film solar battery module shown in FIG. 1 is manufactured by the processes explained above.

The conductive member 10 is constituted by a plate-shaped wiring material, for example, metal such as Au, Ag, Cu, Al, or Ti or alloys thereof. The conductive member 10 can be the one with the surface of the plate-shaped wiring material being solder-plated. For example, solder, ACF (Anisotropic Conductive Film), or conductive adhesive is used as the joining member 9.

When solder is used as the joining member 9, the solder is applied to one or more points on the conductive member 10. When the conductive member 10 is placed on the back surface electrode 8 so as to be along the back surface electrode 8, the points of solder applied are melted one by one and a join between the conductive member 10 and the back surface electrode 8 is formed. For example, by using a multi-head mass-production machine, multi-point simultaneous processes can be performed.

When ACF is used as the joining member 9, film-shaped ACF is cut in advance into a few millimeters squares and the cut pieces of ACF are adhered on the conductive member 10. When the conductive member 10 is placed on the back surface electrode 8 so as to be along the back surface electrode 8, pressure and heat are simultaneously applied to a part to which ACF is adhered and a joining process is performed point by point. The temperature for thermal treatment can be appropriately set depending on the type of resin constituting ACF, and in most cases, the process is performed at a temperature equal to or lower than 200° C.

When the conductive adhesive is used as the joining member 9, the conductive adhesive is coated on the conductive member 10 by a dispenser. By performing thermal treatment after the conductive member 10 is arranged on the back surface electrode 8, electrical connections between the conductive member 10 and the back surface electrode 8 and between the conductive members 10 are formed. To form stronger electrical connections, a pressure can be applied to a connected part.

While the joining member 9 is shown in FIGS. 3-1 and 3-2 such that a point of the joining member 9 is provided at a connected part of the conductive members 10 and three points of the joining member 9 are provided at a connected part between the conductive member 10 and the back surface electrode 8, the present invention is not limited to this example. It suffices that at least one point of the joining member 9 is provided at the connected part of the conductive members 10 and at least one point of the joining member 9 is provided at the connected part between the conductive member 10 and the back surface electrode 8, and the mode in which the joining members 9 are interspersed can be appropriately changed.

By constituting the bus bar wiring 3 by coupling a plurality of conductive members 10 formed to be shorter than the longitudinal direction size of a thin-film solar battery cell to each other, a displacement amount generated by a difference in a thermal expansion coefficient between the translucent substrate 1 and the bus bar wiring 3 is reduced in a conductive member 10. In the bus bar wiring 3, a stress can be relaxed at the bent part of the conductive member 10 in the coupled part of the conductive members 10.

The joining members 9 are interspersed between the conductive member 10 and the back surface electrode 8 and between the conductive members 10, so that the conductive member 10 can be deformed at its part between the joining members 9 at certain flexibility. Among superimposed conductive members 10, an end (an end surface) of one conductive member 10 on the side of the thin-film solar battery cell is not directly joined to another conductive member 10. In an end area T1 where the second end E2 of the conductive member 10-1 opposes the bent conductive member 10-2, the second end E2 of the conductive member 10-1 is not directly joined to an end of the conductive member 10-2 opposing the second end E2. Similarly, in an end area T2 where the second end E2′ of the conductive member 10-2 opposes the bent conductive member 10-3 in the longitudinal direction of the thin-film solar battery cell, the second end E2′ of the conductive member 10-2 is not directly joined to an end of the conductive member 10-3 opposing the second end E2′. Because the joining member 9 is not provided at positions of the end areas T1, T2, . . . of the conductive member 10, deformation is possible at an end of the conductive member 10. Therefore, the stress can be relaxed as compared to a case of joining entire surfaces of the conductive member 10 and the back surface electrode 8 to each other and entire surfaces of the conductive members 10 to each other. It is more desirable that a space is generated between ends of the conductive members 10 opposing to each other in the end areas T1, T2, . . . . The warpage of the translucent substrate 1 and separation of joined parts between the back surface electrode 8 and the bus bar wiring 3 and between the bus bar wiring 3 and the concentrated wiring 11 can be suppressed.

When the bus bar wiring is formed of a copper wire, the copper wire may protrude toward a cell adjacent to an area where a bus bar wiring is formed because of meandering and twist generated when the copper wire is arranged, and thus a short-circuit may occur. For example, assume that when the area where a bus bar wiring is formed has a width of 7 millimeters and the copper wire has a width of 5 millimeters, meandering of about 3 millimeters occurs per 1-meter copper wire. The bus bar wiring formed of a 1-meter copper wire protrudes from the area where a bus bar wiring is formed. In this case, when two 0.5-meter copper wires are connected to each other to constitute the bus bar wiring, meandering can be suppressed to about 1.5 millimeters and the bus bar wiring can be provided within the area where a bus bar wiring is formed. According to the present embodiment, the bus bar wiring 3 is constituted by coupling the conductive members 10 shorter than the longitudinal direction size of a thin-film solar battery cell to each other. Consequently, influences of meandering and twist of the conductive member 10 can be suppressed and problems such as a decrease in efficiency caused by a short-circuit can be avoided.

To obtain effects of suppressing meandering and twist of the conductive member 10, for example, it suffices that the length of each conductive member 10 is equal to or less than 50 centimeters. As the conductive member 10 is shortened, effects of relaxing the stress and suppressing meandering and twist are increased. Considering a burden of a machining process by shortening the conductive member 10, each conductive member 10 has desirably a length of 5 to 30 centimeters, for example.

As long as the bus bar wiring 3 according to the present embodiment is constituted by coupling at least two or more conductive members 10 to each other, effects of the present invention can be obtained. It suffices that the bus bar wiring 3 is the one connected to a positive-side end and to a negative-side end, and the bus bar wiring 3 is not limited to the one directly joined to the back surface electrode 8. For example, also in a case of forming electrode pads on the back surface electrode 8 or the front surface electrode along the longitudinal direction of a thin-film solar battery cell and joining the bus bar wiring 3 to the electrode pads, identical effects can be obtained.

### Second Embodiment

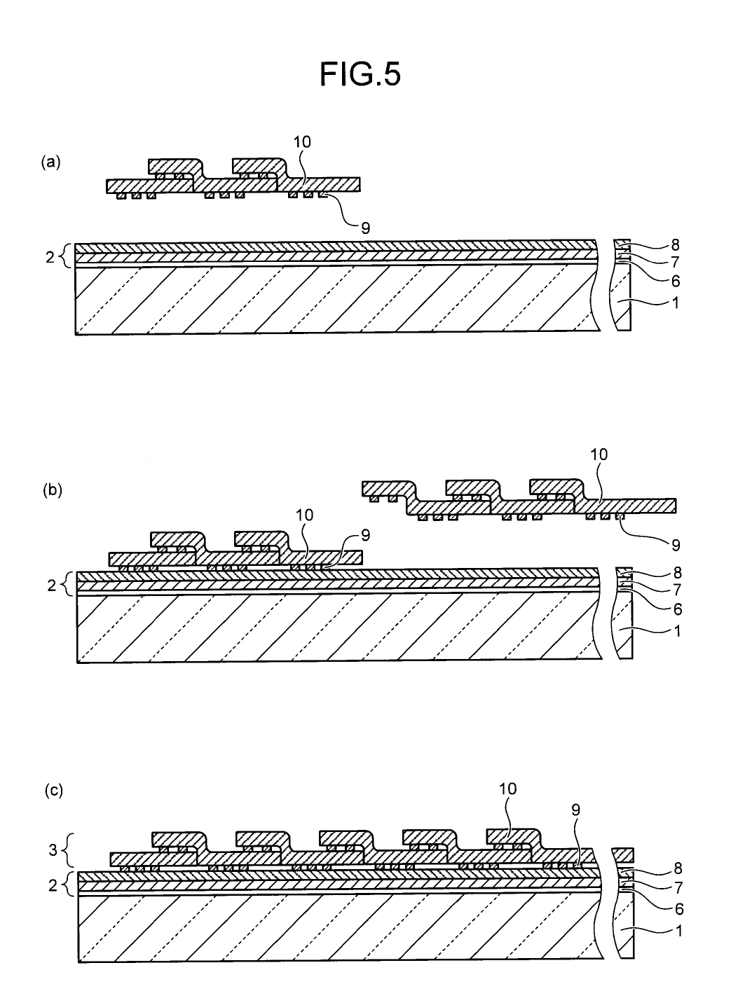

FIG. 5 depicts a schematic cross-sectional configuration in respective processes of a bus-bar-wiring forming step in a method for manufacturing a thin-film solar battery module according to a second embodiment of the present invention. The present embodiment is characterized such that a plurality of conductive members 10 coupled to each other in advance are joined to the thin-film solar battery device 2. Elements identical to those in the first embodiment are denoted by like reference signs and redundant explanations thereof will be omitted.

In a process shown in FIG. 5(a), three conductive members 10 with which the joining members 9 are interspersed in advance are coupled to each other. Similarly to the first embodiment, the coupled part of the conductive members 10 is constituted by joining a part of one conductive member 10 on a part of the other conductive member 10. Next, as shown in FIG. 5(b), a coupled unit of the three conductive members 10 is joined to the back surface electrode 8. Further, the coupled unit of the three conductive members 10 is sequentially coupled on the back surface electrode 8. In this way, as shown in FIG. 5(c), the bus bar wiring 3 with the conductive members 10 being coupled to each other therein is formed on the back surface electrode 8. Also in the case of the present embodiment, a thin-film solar battery module similar to that of the first embodiment can be obtained. It suffices that the conductive member 10 constituting the coupled unit in advance is in plural, and the present invention is not limited to the example of three conductive members 10.

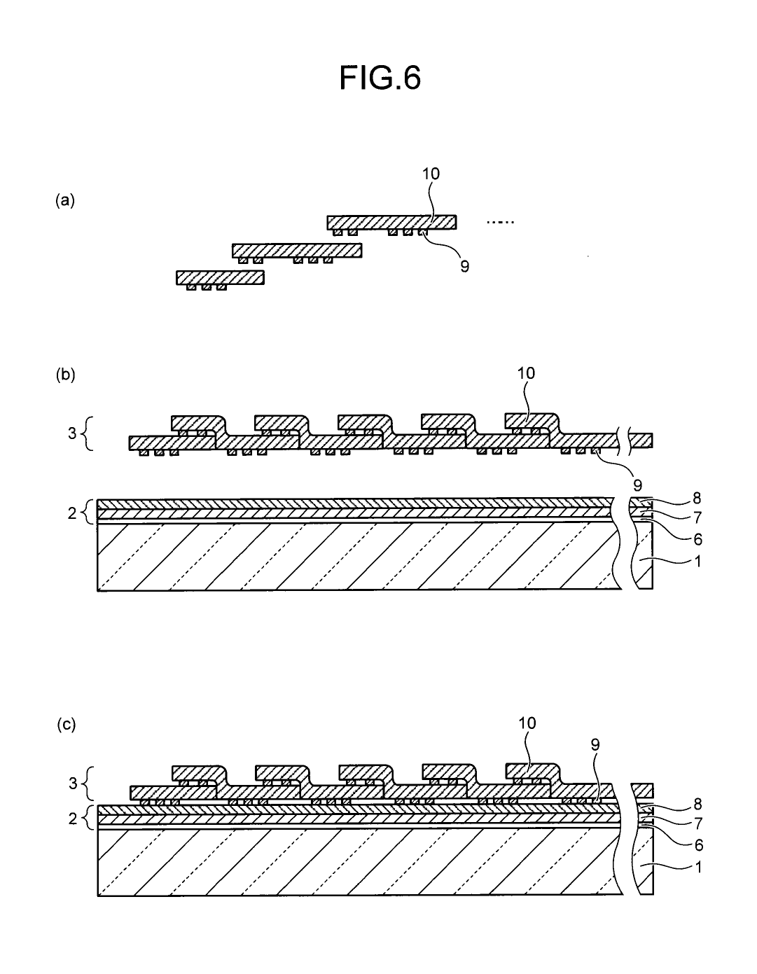

FIG. 6 is an explanatory diagram of a modification of the present embodiment. As shown in FIG. 6(a), by coupling the conductive members 10 with which the joining members 9 are interspersed in advance to each other, as shown in FIG. 6(b), the bus bar wiring 3 that is the coupled unit of the conductive members 10 is formed. At the step shown in FIG. 6(c), the formed bus bar wiring 3 is joined to the back surface electrode 8. Also in the case of the present modification, a thin-film solar battery module similar to that of the first embodiment can be obtained.

### Third Embodiment

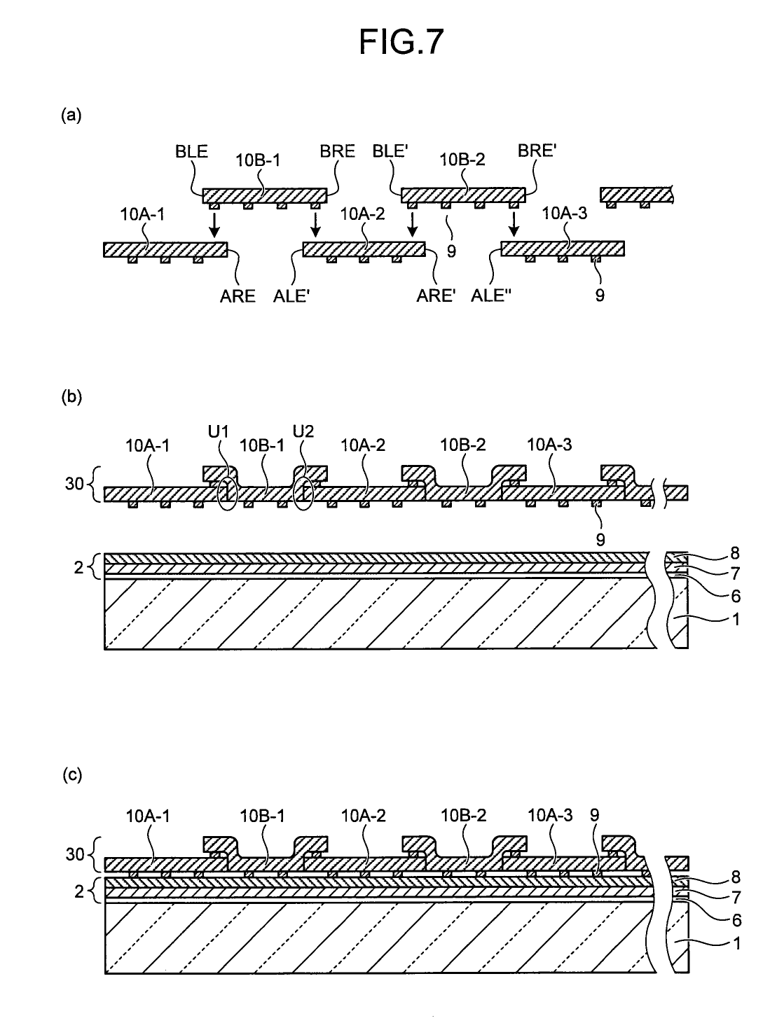

FIG. 7 depicts a schematic cross-sectional configuration in respective processes of a bus-bar-wiring forming step in a method for manufacturing a thin-film solar battery module according to a third embodiment of the present invention. The present embodiment is identical to the second embodiment in that a plurality of conductive members 10 coupled to each other in advance are joined to the thin-film solar battery device 2; however, the third embodiment is different from the second embodiment in the manner that the conductive members 10 are coupled to each other. Elements identical to those in the first embodiment are denoted by like reference signs and redundant explanations thereof will be omitted.

In a process shown in FIG. 7(a), the conductive members 10 with which the joining members 9 are interspersed in advance are arranged so that edge areas of the conductive members 10 adjacent to each other in a longitudinal direction of the conductive member 10 are superimposed. In this case, the conductive members 10 are arranged so that a height-direction position (a thickness-direction position of the conductive member 10) is changed alternately among two positions. With reference to FIG. 7(a), the conductive member 10 arranged on a lower side is determined as a conductive member 10A, and the conductive member 10 arranged on an upper side is determined as a conductive member 10B. As explained later, the conductive member 10A is the conductive member 10 placed on the lower side in a superimposed part after coupling. The conductive member 10B is the conductive member 10 placed on the upper side in the superimposed part after coupling. With reference to FIG. 7(a), the conductive members 10 are arranged in the order of a conductive member 10A-1, a conductive member 10B-1, a conductive member 10A-2, a conductive member 10B-2, a conductive member 10A-3, . . . with their height positions being alternately changed.

Next, as shown in FIG. 7(b), these conductive members 10 are coupled to each other. Similarly to the first embodiment, the coupled part of the conductive members 10 is constituted by joining a part of one conductive member 10 on a part of the other conductive member 10. Note that the present embodiment is characterized such that when a left end BLE serving as a first end of the conductive member 10B-1 is joined to a right end ARE serving as a second end of the conductive member 10A-1 and a right end BRE serving as a second end of the conductive member 10B-1 is joined to a left end ALE′ serving as a first end of the conductive member 10A-2, the ends of the conductive member 10B-1 are joined to parts of edges of the conductive member 10A-1 and the conductive member 10A-2 in a superimposed manner. That is, the left end BLE of the conductive member 10B-1 is joined to a part of the edge of the conductive member 10A-1 on the side the right end ARE in a superimposed manner, and the right end BRE of the conductive member 10B-1 is joined to a part of the edge of the conductive member 10A-2 on the side of a left end ALE′ in a superimposed manner. Similarly, a left end BLE′ of the conductive member 10B-2 is joined to a part of the edge of the conductive member 10A-2 on the side of a right end ARE′ in a superimposed manner, and a right end BRE′ of the conductive member 10B-2 is joined to a part of the edge of the conductive member 10A-3 on the side of a left end ALE″ in a superimposed manner. A longitudinal-direction center part of each conductive member 10B is bent from its parts superimposed on the conductive member 10A between the conductive members 10A adjacent to the conductive member 10B. Other conductive members 10A and conductive members 10B (not shown) are similarly joined and coupled to each other sequentially, so that a bus bar wiring 30 serving as the coupled unit of the conductive members 10 is formed.

In an end area U1 where the right end ARE of the conductive member 10A-1 opposes the conductive member 10B-1 in the longitudinal direction of the conductive member 10, the right end ARE of the conductive member 10A-1 is not directly joined to an end of the bent conductive member 10B-1 opposing the right end ARE. Similarly, in an end area U2 where the left end ALE′ of the conductive member 10A-2 opposes the conductive member 10B-1, the left end ALE′ of the conductive member 10A-2 is not directly joined to an end of the bent conductive member 10B-1 opposing the left end ALE′. The joining member 9 is not arranged at positions of the end areas U1, U2, . . . of the conductive member 10.

Next, as shown in FIG. 7(c), the bus bar wiring 30 with the conductive members 10 being coupled to each other therein is joined to the thin-film solar battery device 2 by the joining member 9. That is, the coupled unit of the conductive members 10 is successively joined to the back surface electrode 8 by the joining member 9 in the order of the conductive member 10A-1, the conductive member 10B-1, the conductive member 10A-2, the conductive member 10B-2, . . . .

By performing the steps described above, it is possible to manufacture a thin-film solar battery module that can avoid influences of meandering possessed by a wire material for the conductive member 10, to relax deformation due to the stress generated between different members, and to obtain effects identical to those in the first embodiment. That is, also in the present embodiment, by constituting the bus bar wiring 30 by coupling the conductive members 10 shorter than the longitudinal-direction size of a thin-film solar battery cell to each other as in the first embodiment, the thin-film solar battery module that can suppress influences of meandering and twist of the conductive member 10 and avoid problems such as a decrease in efficiency caused by a short-circuit can be obtained.

While on the conductive member 10A, two points of the joining member 9 are interspersed equally in the length direction of the wire material in parts connected to the conductive member 10B and two points of the joining member 9 are interspersed equally in the length direction of the wire material in its part connected to the back surface electrode 8, and on the conductive member 10B, three points of the joining member 9 are interspersed equally in the length direction of the wire material in its part connected to the back surface electrode 8 in FIG. 7, the present invention is not limited to this example.

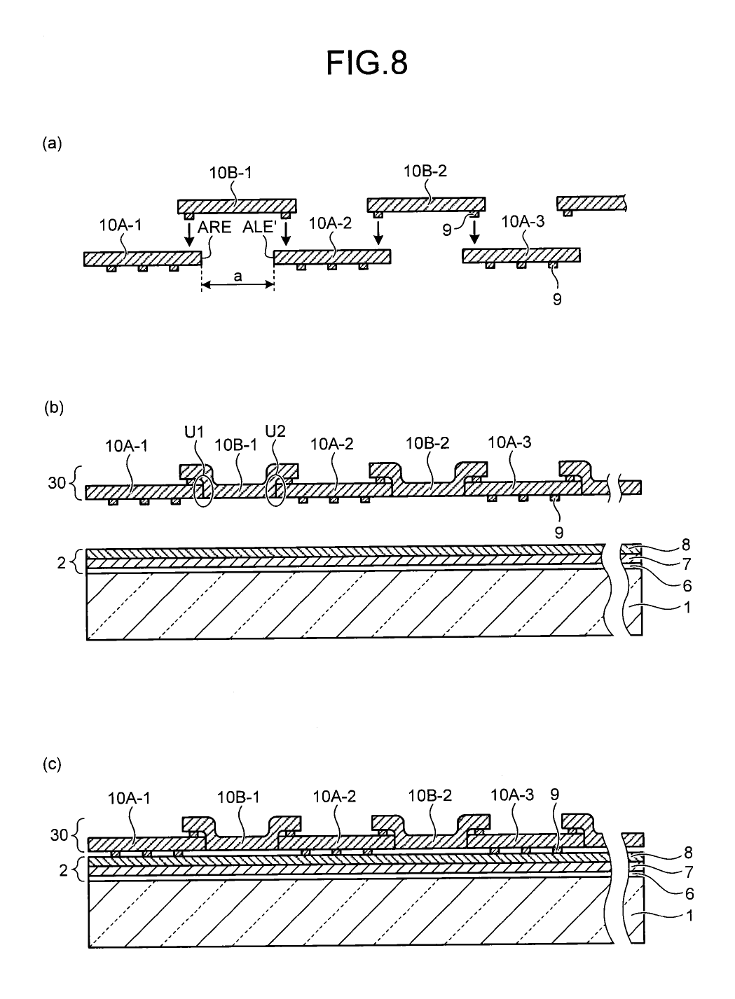

FIG. 8 is an explanatory diagram of a modification of the third embodiment. In a process shown in FIG. 8(a), the conductive member 10A and the conductive member 10B with which the joining members 9 are interspersed in advance are arranged so that edge areas of the conductive members 10 adjacent to each other in the longitudinal direction of the conductive member 10 are superimposed as in the case of FIG. 7(a). While three joining members 9 are arranged on the conductive members 10A-1 to 10A-3 equally in the length direction of the wire material, the joining member 9 is arranged only at edge areas of the conductive member 10B-1 and the conductive member 10B-2 in the length direction of the wire material and is not arranged near a center in the length direction of the wire material.

Next, in a process of FIG. 8(b), these conductive members 10 are coupled to each other as in the case of the third embodiment described above. That is, ends of the conductive member 10B-1 are joined to a part of the edge of the conductive member 10A-1 on the side of the right end ARE and to a part of the edge of the conductive member 10A-2 on the side of the left end ALE′ in a superimposed manner. Similarly, ends of the conductive member 10B-2 are joined to a part of the edge of the conductive member 10A-2 on the side of the right end ARE′ and to a part of the edge of the conductive member 10A-3 on the side of the left end ALE″ in a superimposed manner. The longitudinal direction center of the conductive member 10B-1 is bent from parts superimposed on the conductive member 10A-1 and on the conductive member 10A-2 between the conductive member 10AA-1 and the conductive member 10A-2 adjacent to the conductive member 10B-1. Other conductive members 10A and conductive members 10B are similarly joined and coupled to each other sequentially, so that the bus bar wiring 30 serving as the coupled unit of the conductive members 10 is formed.

The joining member 9 is not arranged near centers of the conductive member 10B-1 and the conductive member 10B-2 in the length direction of the wire material. In the end area U1 of the conductive member 10 where the right end ARE of the conductive member 10A-1 opposes the conductive member 10B-1, the right end ARE of the conductive member 10A-1 is not directly joined to an end of the bent conductive member 10B-1 opposing the right end ARE. In the end area U2 of the conductive member 10 where the left end ALE′ of the conductive member 10A-2 opposes the conductive member 10B-1, the left end ALE′ of the conductive member 10A-2 is not directly joined to an end of the bent conductive member 10B-1 opposing the left end ALE′.

Next, as shown in FIG. 8(c), the bus bar wiring 30 with the conductive members 10 being coupled to each other therein is joined to the thin-film solar battery device 2 by the joining member 9 as in the case of the third embodiment described above. That is, the coupled unit of the conductive members 10 is successively joined to the back surface electrode 8 in the order of the conductive member 10A-1, the conductive member 10B-1, the conductive member 10A-2, the conductive member 10B-2, . . . .

At this time, because the joining member 9 is not arranged near the centers of the conductive member 10B-1 and the conductive member 10B-2 in the length direction of the wire material, the conductive member 10A (the conductive member 10A-1, the conductive member 10A-2, the conductive member 10A-3, . . . ) is joined to the thin-film solar battery device 2; however, the conductive member 10B (the conductive member 10B-1, the conductive member 10B-2, . . . ) is not joined to the thin-film solar battery device 2.

By performing these steps described above, it is possible to manufacture a thin-film solar battery module that can avoid influences of meandering possessed by the wire material for the conductive member 10, to relax deformation due to the stress generated between different members, and to obtain effects identical to those in the first embodiment. That is, by constituting the bus bar wiring 30 by coupling the conductive members 10 shorter than the longitudinal-direction size of a thin-film solar battery cell to each other as in the first embodiment, the thin-film solar battery module that can suppress influences of meandering and twist of the conductive member 10 and avoid problems such as a decrease in efficiency caused by a short-circuit can be obtained.

When a space a between the conductive members 10A is narrow, bending of the conductive member 10B is reduced. However, because the joining member 9 is not arranged in the end area U1, the end area U2, and other areas corresponding to these end areas, the conductive member 10A and the conductive member 10B superimposed to each other are not joined to each other in these areas. The conductive member 10B thus has certain flexibility near the longitudinal direction center and can be expanded and contracted and bent. Therefore, a thin-film solar battery module capable of obtaining effects identical to those in the first embodiment can be formed.

In FIG. 8, while the conductive member 10A is interspersed with the joining members 9, the manner that the joining members 9 are arranged is not limited to this example. That is, it suffices that of super imposed conductive members 10, an end of one conductive member 10 on the side of the thin-film solar battery cell in the longitudinal direction of a thin-film solar battery cell is not directly joined to another conductive member 10. The joining member 9 can be provided on the conductive member 10A to be over the longitudinal-direction full width of the thin-film solar battery cell.

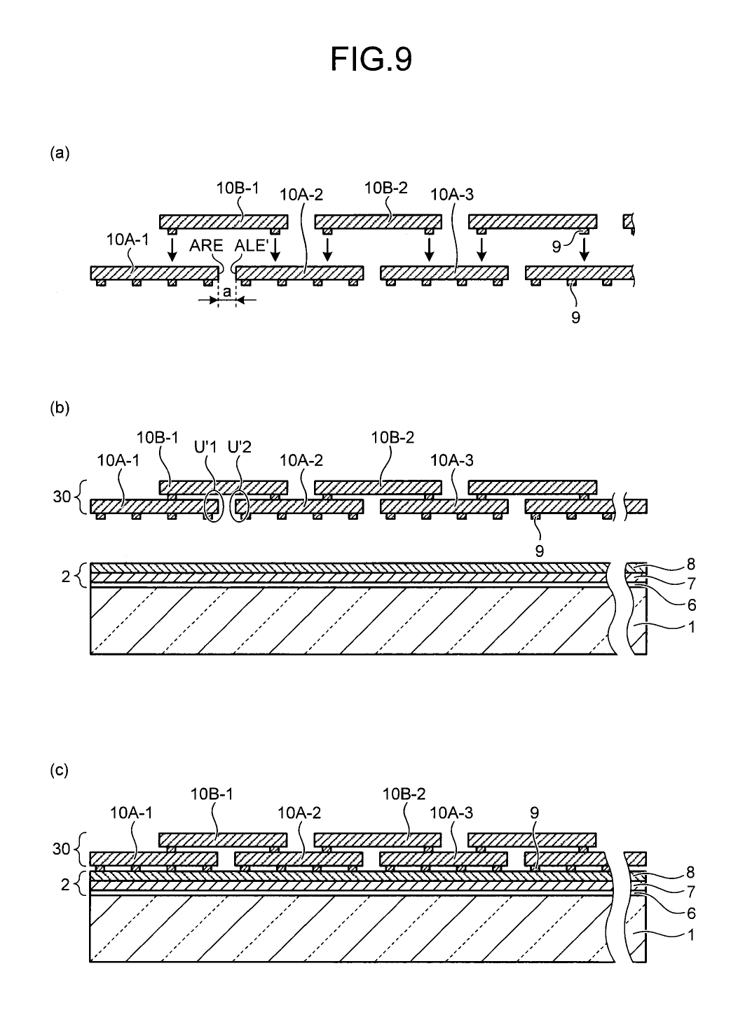

FIG. 9 is an explanatory diagram of another modification of the third embodiment. FIGS. 9(a), (b), and (c) correspond to FIGS. 8(a), (b), and (c), respectively. In the mode shown in FIG. 9, the same configurations and the same manufacturing method as in the mode shown in FIG. 8 are applied except that the space between conductive members 10A adjacent to each other in the longitudinal direction of a thin-film solar cell is considerably narrow and the conductive member 10B is not bent. That is, in a process shown in FIG. 9(a), the conductive member 10A and the conductive member 10B arranged so that the space a is considerably narrower than that of FIG. 8(a). Next, in a process shown in FIG. 9(b), under such a condition, the conductive member 10A and the conductive member 10B are joined and coupled to each other as in the case of FIG. 8(b), so that the bus bar wiring 30 serving as the coupled unit of the conductive members 10 is formed. In a process shown in FIG. 9(c), the bus bar wiring 30 with the conductive members 10 being coupled to each other therein is joined to the thin-film solar battery device 2 by the joining member 9 as in the case of FIG. 8(b).

According to this mode, because the space a serving as a space between the conductive member 10A-1 and the conductive member 10A-2 is considerably narrow, the conductive member 10B-1 is not bent. Similarly, other conductive members 10B are not bent. The conductive member 10A is not directly joined to the conductive member 10B in an end area U′1 of the conductive member 10A-1 on the side of the right end ARE, an end area U′2 of the conductive member 10A-2 on the side of the left end ALE′, and other areas corresponding to these areas. Also in the present modification, the center of the conductive member 10B has certain flexibility, and a thin-film solar battery module capable of obtaining effects identical to those in the first embodiment can be formed.

### INDUSTRIAL APPLICABILITY

As described above, according to the thin-film solar battery module and the method for manufacturing the same of the present invention, it is possible to avoid a decrease in power generation efficiency caused by influences of meandering of a wiring material and to suppress warpage of a substrate and separation of a connected part of an electrode and a wiring, and the thin-film solar battery module and the method for manufacturing the same are useful to prevent the manufacturing yield from being decreased.

### REFERENCE SIGNS LIST

2 THIN-FILM SOLAR BATTERY DEVICE
3, 30 BUS BAR WIRING
8 BACK SURFACE ELECTRODE
9 JOINING MEMBER
10 CONDUCTIVE MEMBER

1. A thin-film solar battery module comprising:
a thin-film solar battery device constituted by serially connecting a plurality of thin-film solar battery cells to each other; and
a bus bar wiring provided at a positive-side end and a negative-side end of the thin-film solar battery device, wherein
the bus bar wiring is constituted by coupling a plurality of conductive members to each other in a partially superimposed manner.

2. The thin-film solar battery module according to claim 1, further comprising:
a joining member that joins the conductive members to each other at a coupled part of the conductive members, wherein
the joining member is not arranged at an end of the conductive member.

3. A method for manufacturing a thin-film solar battery module, the method comprising:
a step of forming a thin-film solar battery device with a plurality of thin-film solar battery cells being serially connected to each other therein; and
a bus-bar-wiring forming step of forming a bus bar wiring at a positive-side end and a negative-side end of the thin-film solar battery device, wherein
at the bus-bar-wiring forming step, the bus bar wiring is formed by coupling a plurality of conductive members to each other in a partially superimposed manner.

4. The method for manufacturing a thin-film solar battery module according to claim 3, wherein at the bus-bar-wiring forming step, the conductive members are coupled to each other on the thin-film solar battery device by joining a next conductive member to a conductive member previously joined to the thin-film solar battery device and to the thin-film solar battery device.

5. The method for manufacturing a thin-film solar battery module according to claim 3, wherein
at the bus-bar-wiring forming step, the conductive members are coupled to each other by sequentially joining the conductive members to each other, and
the conductive members coupled to each other are joined to the thin-film solar battery device.

6. The method for manufacturing a thin-film solar battery module according to claim 5, wherein at the bus-bar-wiring forming step, a part of the conductive members coupled to each other is joined to the thin-film solar battery device.

7. The method for manufacturing a thin-film solar battery module according to claim 4, wherein
at the bus-bar-wiring forming step,
the conductive members are joined to each other by a joining member,
the conductive member is joined to the thin-film solar battery device, and
the joining member that joins the conductive members to each other is not arranged at an end of the conductive member.

8. The method for manufacturing a thin-film solar battery module according to claim 5, wherein
at the bus-bar-wiring forming step,
the conductive members are joined to each other by a joining member,
the conductive member is joined to the thin-film solar battery device, and
the joining member that joins the conductive members to each other is not arranged at an end of the conductive member.
